(19) United States
(12) Patent Application Publication
(10) Pub. No.: US 2011/0175686 A1
(43) Pub. Date: Jul. 21, 2011

(54) HIGH FREQUENCY SECOND HARMONIC OSCILLATOR

(75) Inventors: Shinsuke Watanabe, Tokyo (JP); Yoshihiro Tsukahara, Tokyo (JP); Ko Kanaya, Tokyo (JP); Shinichi Miwa, Tokyo (JP)

(73) Assignee: MITSUBISHI ELECTRIC CORPORATION, Tokyo (JP)

(21) Appl. No.: 12/911,764

(22) Filed: Oct. 26, 2010

(30) Foreign Application Priority Data
Jan. 15, 2010 (JP) 2010-007092

(51) Int. Cl. H03B 5/12

(52) U.S. Cl. 331/117 FE

(57) ABSTRACT

A high frequency second harmonic oscillator includes a transistor, a first signal line connected at a first end to the base or gate of the transistor, a first shunt capacitor connected at a first end to a second end of the first signal line and at a second end to ground, a second signal line connected at a first end to the collector or drain of the transistor, a second shunt capacitor connected at a first end to a second end of the second signal line and at a second end to ground, and a high capacitance capacitor connected between the first signal line and the second signal line. The first signal line has a length equal to an odd integer multiple of one quarter of the wavelength of a fundamental signal, plus or minus one-sixteenth of the wavelength of the fundamental signal.

### BACKGROUND OF THE INVENTION

1. Field of the Invention

The present invention relates primarily to high frequency second harmonic oscillators operating with microwaves or millimeter waves.

2. Background Art

The widespread use of high frequency wireless devices such as in-vehicle radar and cellular phones has increased the demand for higher performance oscillators having an output frequency of over 1 GHz. An oscillator is a circuit that internally oscillates to generate and output a high frequency electrical signal. Oscillators incorporate an active device such as a transistor to amplify the generated high frequency electrical signal.

An oscillator which outputs a signal of the same frequency as the oscillating frequency is referred to as a “fundamental oscillator.” On the other hand, an oscillator which outputs a signal of a frequency twice the oscillating frequency is referred to as a “second harmonic oscillator.” Second harmonic oscillators have an advantage over fundamental oscillators in that they are less susceptible to external load variations, since they includes a virtual short point, as described later. This advantage enables the manufacture of a second harmonic oscillator having high performance even if the maximum oscillating frequency achievable with its transistor is low. The frequency at which oscillation occurs is referred to as the “fundamental frequency,” and an electrical signal of the fundamental frequency is referred to as a “fundamental signal.” Further, the frequency twice the fundamental frequency is referred to as the “second harmonic frequency,” and an electrical signal of the second harmonic frequency is referred to as a “second harmonic signal.”

A typical series-positive-feedback second-harmonic oscillator will be described with reference to FIG. 14. FIG. 14 is a circuit diagram of a typical series-positive-feedback second-harmonic oscillator 100. Referring to FIG. 14, a bias terminal 113 and a bias terminal 114 are used to supply a base voltage and a collector voltage, respectively, to a transistor 108. The bias terminal 113 is connected to the base terminal of the transistor 108 through a transmission line 15 and also connected to an open stub so that the bias terminal 113 is not affected by the fundamental signal. Further, the bias terminal 114 is connected to the collector terminal of the transistor 108 through a transmission line 117 so that the bias terminal 114 is not affected by the second harmonic signal. A capacitor 111 prevents leakage of the DC components of the collector voltage and collector current to the output of the oscillator.

Further, an open stub 109 is connected to the electrical signal line electrically connected between the transistor 108 and an output terminal 112. The open stub 109 has a length equal to a quarter of the wavelength of the fundamental signal. A region whose potential is not affected by the fundamental signal, that is, a virtual short point 110, is established at the junction of the open stub 109 with the signal line. The fundamental signal does not propagate beyond this virtual short point 110 toward the output terminal 112. The second harmonic signal, on the other hand, is not affected by the open stub 109 and the virtual short point 110. As a result, the second harmonic signal propagates to the output terminal 112 and is output from the oscillator 100.

In the oscillator 100 shown in FIG. 4, the virtual short point 110 is established by the open stub 109, as described above. In addition to such oscillators, push-push oscillators are often used, which are second harmonic oscillators in which a plurality of oscillators are coupled together to establish a virtual short point. An open stub is usually used when the power loss in the stub is low and the fundamental frequency is sufficiently high. Otherwise, push-push oscillators are usually used.

It should be noted that oscillators are described in Published Japanese Translation of PCT Application No. 2007-501574 and Japanese Laid-Open Patent Publication No. 2009-147899.

Two important characteristics of oscillators are the output frequency and phase noise. First the output frequency will be described.

The output frequency of an oscillator is the frequency of its output signal. This means that the output frequency of a second harmonic oscillator is the second harmonic frequency (described above). It is desirable that the oscillator incorporated in a high frequency wireless device be constructed so as to output a signal directly usable by other components of the wireless device without multiplying the frequency of the signal. The reason for this is that the use of a frequency multiplier complicates the construction of the wireless device and hence increases its cost, although the oscillator is allowed to generate a signal of a lower frequency than the frequency used within the device. Since the operating frequency of wireless devices is increasing, there is a need to increase the output frequency of their oscillators.

On the other hand, the phase noise of an oscillator is a measure of the stability of the output frequency of the oscillator. When an oscillator is used as a radar or communication device, the phase noise of the oscillator affects the distance measuring accuracy or communication error rate. Therefore, the lower the phase noise, the better. It will be noted that the Q value of the resonator may be increased to reduce the phase noise. The Q value of a resonator is a measure of the amount of energy stored in the resonator. That is, the Q value also serves as a measure of the invariability of the fundamental frequency of the oscillator. However, increasing the Q value makes it difficult to vary the output frequency of the oscillator even if the oscillator is provided with variable output frequency capability. That is, the output frequency of the oscillator can be varied only over a narrow range. In order to avoid this problem, phase noise controlling methods other than increasing the Q value have been proposed.

The potential change at various locations within an oscillator is a factor in increasing the phase noise of the oscillator. There are two causes for this potential change. One is the second harmonic signal left in the oscillator, and the other is the 1/f noise signal generated by the transistor or transistors. An oscillator having a construction designed by taking into account the second harmonic signal left in the oscillator has been disclosed in “A Ka-Band Second Harmonic Oscillator with Optimized Harmonic Load,” 2007 Technical Report of IEICE, vol. 107, No. 355, pp. 29-32, November 2007 (hereinafter referred to as “reference literature 1”). In this oscillator, the circuit electrically connected to the base (or gate) of the transistor acts as a short circuit at the second harmonic frequency. This increases the amount of second harmonic signal output from the oscillator, resulting in reduced phase noise. On the other hand, an oscillator having a construction designed by taking into account the 1/f noise signal generated by its transistor has been disclosed in “A novel RFIC for UHF oscillators,” IEEE Radio Frequency Integrated Circuits Symp. Digest, pp. 53-56, 2000 (hereinafter referred to as “reference literature 2”). This oscillator includes a 1/f noise signal feedback circuit. The feedback circuit applies an electrical signal to the base (or gate) of the transistor, which signal is 180° out of phase with the 1/f noise signal generated at the base (or gate) of the transistor. This cancels out the 1/f noise signal, resulting in reduced phase noise.

The construction of the oscillator described in reference literature 1 allows the second harmonic signal left in the oscillator to propagate from the oscillator, but it has no impact on the 1/f noise signal. Therefore, the construction of reference literature 1 does not sufficiently reduce the phase noise of an oscillator if the phase noise is primarily caused by the 1/f noise signal in the oscillator.

The construction of the oscillator described in reference literature 2 has the following three disadvantages. First, it has only a slight effect in reducing the phase noise. The reason for this is because the transistor in the feedback circuit also serves as a 1/f noise signal source. Secondly, adding a feedback circuit to an existing oscillator results in a change in the oscillating frequency of the oscillator or prevents oscillation of the oscillator, making it necessary to redesign the oscillator. Thirdly, the construction of reference literature 2 has no impact on the second harmonic signal left in the oscillator. Therefore, it has only a slight effect in reducing the phase noise of an oscillator if the phase noise is primarily caused by the second harmonic signal. Thus, the construction of the oscillator described in reference literature 2 also does not sufficiently reduce the phase noise.

### SUMMARY OF THE INVENTION

The present invention has been made to solve the above problems. It is, therefore, an object of the present invention to provide a high frequency second harmonic oscillator having a construction that ensures low phase noise characteristics of the oscillator by eliminating all possible causes of increase in the phase noise.

According to one aspect of the present invention, a high frequency second harmonic oscillator includes a transistor, a first electrical signal line electrically connected at one end to the base or gate of the transistor, a first shunt capacitor connected at one end to the other end of the first electrical signal line and at the other end to ground, a second electrical signal line electrically connected at one end to the collector or drain of the transistor, a second shunt capacitor connected at one end to the other end of the second electrical signal line and at the other end to ground, and a high capacitance capacitor connected between the other end of the first electrical signal line and the other end of the second electrical signal line. The first electrical signal line has a length equal to a wavelength between an odd multiple of a quarter of the wavelength of the fundamental signal plus and minus one-sixteenth of the wavelength of the fundamental signal.

Other and further objects, features and advantages of the invention will appear more fully from the following description.

### BRIEF DESCRIPTION OF THE DRAWINGS

FIG. 1 is a circuit diagram illustrating the construction of a high frequency second harmonic oscillator of the first embodiment;

FIG. 2 is a circuit diagram used to explain the DC signals;

FIG. 3 is a circuit diagram used to explain the fundamental signal;

FIG. 4 is a circuit diagram used to explain the second harmonic signal;

FIG. 5 is a circuit diagram used to explain the low frequency 1/f noise signal;

FIG. 6 shows the simulation results of the second harmonic oscillator A;

FIG. 7 shows the simulation results of the second harmonic oscillator B;

FIG. 8 shows the frequency dependency of the 1/f noise power;

FIG. 9 is a circuit diagram illustrating the construction of a high frequency second harmonic oscillator of the second embodiment;

FIG. 10 is a circuit diagram illustrating the construction of a high frequency second harmonic oscillator of the third embodiment;

FIG. 11 is a circuit diagram illustrating the construction of a high frequency second harmonic oscillator of the fourth embodiment;

FIG. 12 is a circuit diagram illustrating the construction of a high frequency second harmonic oscillator of the fifth embodiment;

FIG. 13 is a circuit diagram illustrating the construction of a high frequency second harmonic oscillator of the sixth embodiment; and

FIG. 14 is a circuit diagram illustrating the construction of a high frequency second harmonic oscillator of the prior art.

### DETAILED DESCRIPTION OF THE PREFERRED EMBODIMENTS

### First Embodiment

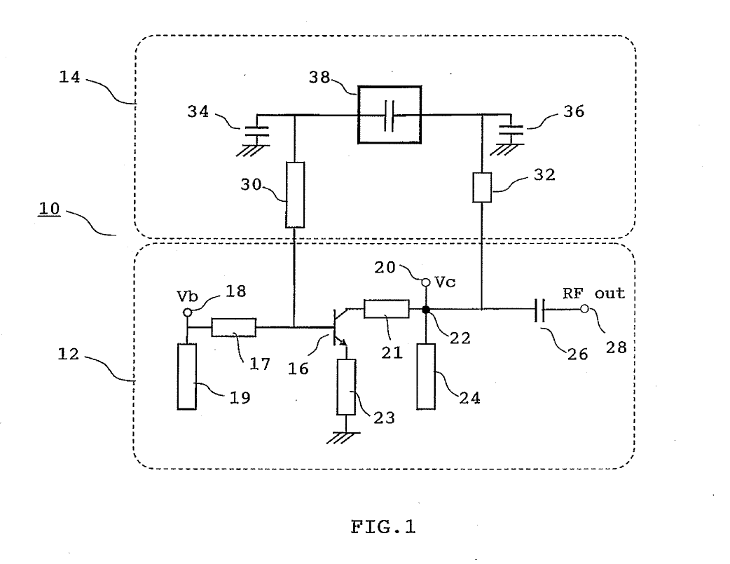

A first embodiment of the present invention will be described with reference to FIGS. 1 to 8. It should be noted that throughout the description of the first embodiment, certain of the same materials and the same or corresponding components are designated by the same reference numerals and described only once. This also applies to other embodiments of the invention subsequently described.

FIG. 1 is a circuit diagram illustrating the construction of a high frequency second harmonic oscillator 10 of the present embodiment. This high frequency second harmonic oscillator 10 has a series feedback configuration and includes an oscillating circuit 12 and a feedback circuit 14. The following description will be directed to the constructions of the oscillating circuit 12 and the feedback circuit 14.

The oscillating circuit 12 includes a transistor 16. The transistor 16 is a bipolar transistor made of indium gallium arsenide. A bias terminal 18 and an open stub 19 are connected to the base terminal of the transistor 16 through a transmission line 17. A bias terminal 20 is connected to the collector terminal of the transistor 16 through a transmission line 21. An output terminal 28 is connected to the collector terminal of the transistor 16 through the transmission line 21 and a capacitor 26. Further, an open stub 24 is connected at one end between the transmission line 21 and the capacitor 26. The junction of the open stub 24 with the transmission line 21 acts as a virtual short point 22 beyond which the fundamental signal does not propagate. The emitter terminal of the transistor 16 is grounded through a transmission line 23.

The feedback circuit 14 includes a first electrical signal line 30 connected at one end to the base terminal of the transistor 16. The feedback circuit 14 also includes a first shunt capacitor 34 connected at one end to the other end of the first electrical signal line 30 and at the other end to ground. The feedback circuit 14 also includes a second electrical signal line 32 connected at one end between the virtual short point 22 and the capacitor 26, that is, connected to the collector terminal of the transistor 16 through the transmission line 21. Further, the feedback circuit 14 also includes a second shunt capacitor 36 connected at one end to the other end of the second electrical signal line 32 and at the other end to ground. A high capacitance capacitor 38 is connected between the other end of the first electrical signal line 30 and the other end of the second electrical signal line 32.

The first electrical signal line 30 has a length equal to an odd multiple of a quarter of the wavelength of the fundamental signal. The high capacitance capacitor 38 has a capacitance five times or more greater than the capacitance of the first shunt capacitor 34 or the second shunt capacitor 36, whichever is higher. The open stub 24 has a length equal to an odd multiple of a quarter of the wavelength of the fundamental signal. Further, the lengths of the transmission lines 17, 21, and 23 and the open stub 19 are selected so that the oscillator oscillates to generate the desired fundamental signal. This completes the description of the construction of the high frequency second harmonic oscillator of the present embodiment.

The effect of the feedback circuit 14 on the oscillating circuit 12 will now be described. Specifically, the following describes, separately, the DC signals (or zero Hz signals), the fundamental signal, the second harmonic signal, and the low frequency 1/f noise signal in the oscillator.

The DC signals will now be described. FIG. 2 is a circuit diagram used to explain the DC signals. In FIG. 2, the solid lines indicate the portions of the oscillator 10 (or the oscillating circuit 12) that are affected by the DC signals. The dashed lines, on the other hand, indicate the portions of the oscillator 10 whose constructions do not affect the DC characteristics of the oscillator 10; that is, the DC characteristics of the oscillator 10 do not change even if the lengths of the transmission lines in these portions are changed or a series resistance is added, etc. That is, the lines open at one end, as well as those connected at one end in series with a capacitor, do not affect the DC signals. Therefore, only those portions of the oscillator 10 indicated by the solid lines in FIG. 2 affect the DC signals. This means that the addition or deletion of the feedback circuit 14 to the oscillating circuit 12 does not affect the DC characteristics of the oscillator.

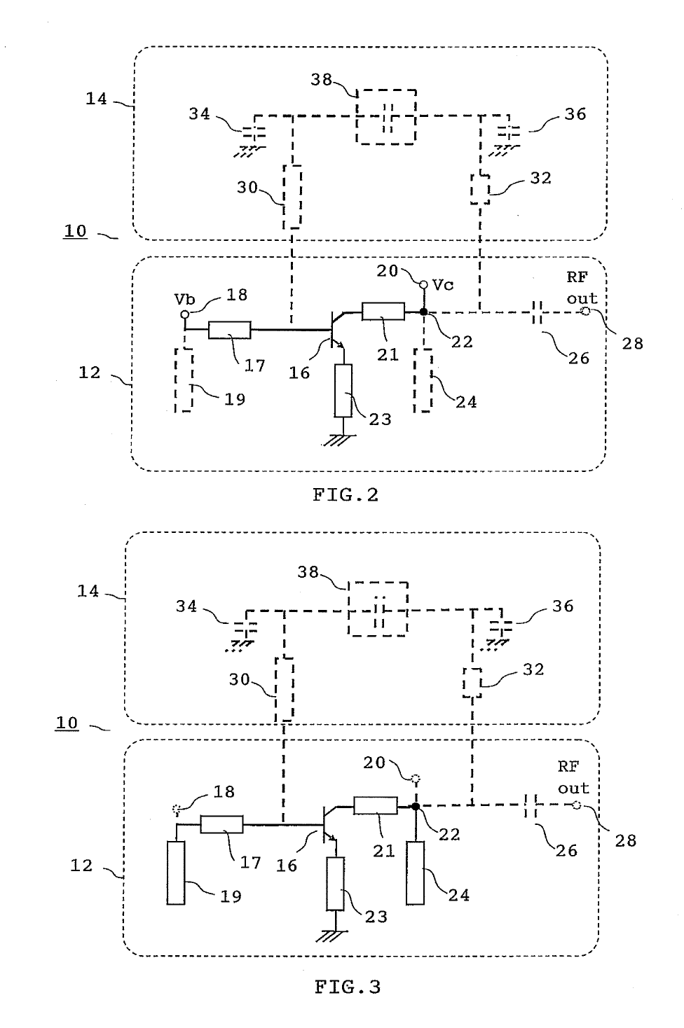

The fundamental signal will now be described. FIG. 3 is a circuit diagram used to explain the fundamental signal. In FIG. 3, the solid lines indicate the portions of the oscillator 10 that are affected by the fundamental signal. The dashed lines, on the other hand, indicate the portions of the oscillator 10 whose circuit configurations do not affect the fundamental signal in the oscillator 10. Specifically, the fundamental signal does not propagate beyond the virtual short point 22 toward the output terminal 28. Therefore, the fundamental signal is not affected by any change in the portion of the oscillator 10 on the same side of the virtual short point 22 as the output terminal 28. Further, the first electrical signal line 30, which is connected at one end to ground through the first shunt capacitor 34, acts as an open circuit at the fundamental frequency. Therefore, the connection or disconnection of the first electrical signal line 30 does not affect the fundamental signal. This means that the addition or deletion of the feedback circuit 14 to the oscillating circuit 12 does not affect the characteristics of the oscillator 10 with respect to the fundamental signal. Thus, the connection of the feedback circuit 14 to the oscillating circuit 12 does not affect the DC and fundamental frequency characteristics of the oscillating circuit 12, with the result that there is no change in the oscillating frequency.

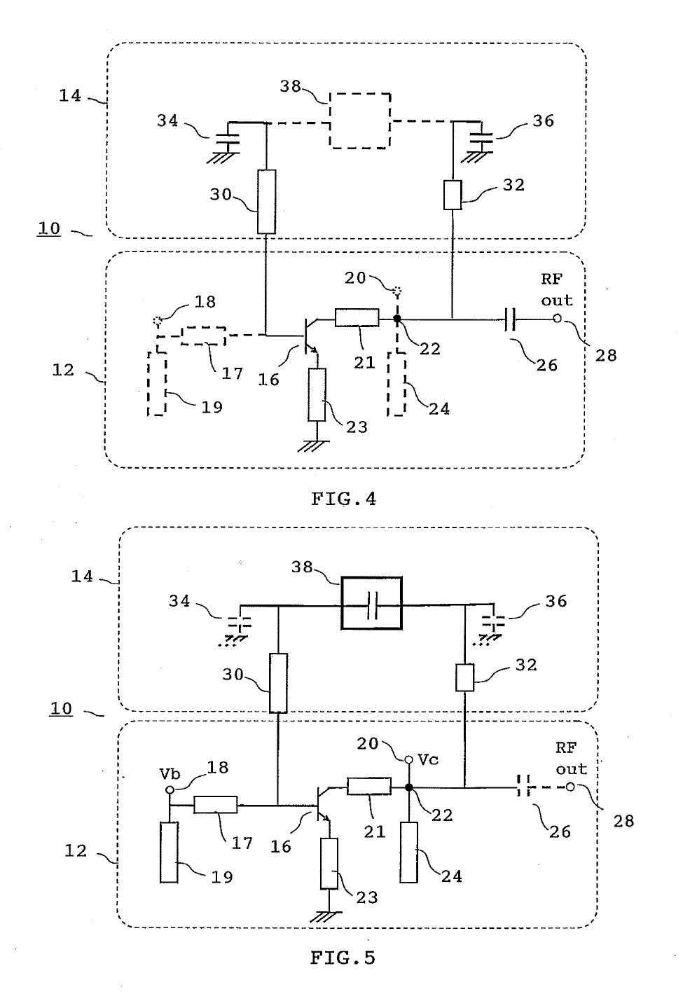

The second harmonic signal will now be described. FIG. 4 is a circuit diagram used to explain the second harmonic signal. In FIG. 4, the solid lines indicate the portions of the oscillator 10 that are affected by the second harmonic signal. The first electrical signal line 30, which is connected at one end to ground through the first shunt capacitor 34, acts as a short circuit at the second harmonic frequency. Since the first electrical signal line 30 is connected to the base terminal of the transistor 16, the base of the transistor 16 is short-circuited to ground at the second harmonic frequency. This promotes the propagation of the second harmonic signal from the oscillating circuit 12, thereby reducing fluctuations in the base voltage of the transistor 16 due to the second harmonic signal and hence reducing the phase noise.

The low frequency 1/f noise signal will now be described. FIG. 5 is a circuit diagram used to explain the low frequency 1/f noise signal. In FIG. 5, the solid lines indicate the portions of the oscillator 10 that are affected by the low frequency 1/f noise signal. The low frequency 1/f noise signal (0.001 GHz or less) does not pass through the first shunt capacitor 34 and the second shunt capacitor 36, which have a low capacitance, although it passes through the high capacitance capacitor 38. Therefore, the low frequency 1/f noise signal generated from the transistor 16 affects only those portions of the oscillator 10 indicated by the solid lines in FIG. 5. The low frequency 1/f noise signal generated from the base of the transistor 16 passes through the transistor and as a result undergoes a 180 degree phase change. The resulting signal then passes through the second electrical signal line 32, the high capacitance capacitor 38, and the first electrical signal line 30 and returns to the base of the transistor 16. This feedback signal cancels out the low 1/f noise signal, reducing the phase noise.

As described above, the high frequency second harmonic oscillator 10 of the present embodiment includes the first shunt capacitor 34 and the second shunt capacitor 36 that act as open circuits to the 1/f noise signal of 0.001 GHz or less although they act as short circuits at the fundamental and second harmonic frequencies. Further, the oscillator 10 also includes the high capacitance capacitor 38 for canceling out the low frequency 1/f noise signal. That is, the feedback circuit 14 of the oscillator 10 is adapted to perform different types of processing on the second harmonic signal and the low frequency 1/f noise signal (which both cause phase noise) to reduce the phase noise in the oscillator.

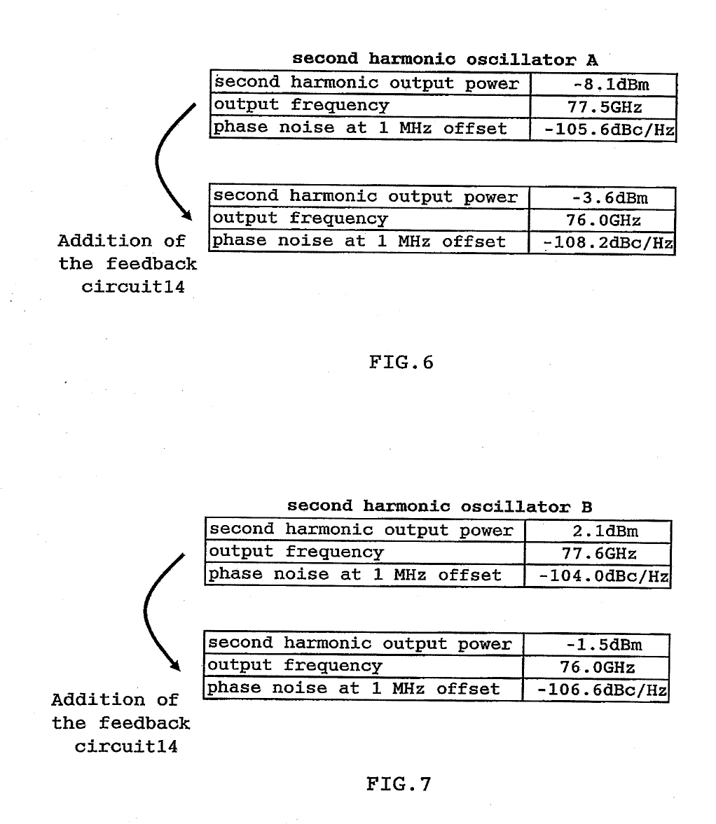

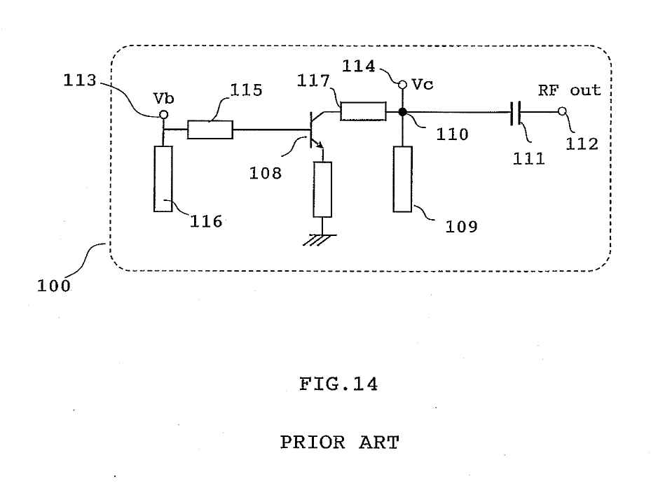

The characteristics of two types of second harmonic oscillators (namely, second harmonic oscillators A and B) were simulated to verify the phase noise-reducing effect of the construction of the high frequency second harmonic oscillator 10 of the present embodiment. The second harmonic oscillator A has the same construction as the second harmonic oscillator shown in FIG. 14 and has relatively poor phase noise characteristics since the second harmonic signal is left in the oscillator. Further, the transistor in this oscillator generates 1/f noise. The upper table in FIG. 6 shows the simulation results of the second harmonic output power, the output frequency, and the phase noise (at 1 MHz offset) of the second harmonic oscillator A alone (without the feedback circuit 14). The lower table in FIG. 6, on the other hand, shows the simulation results of the second harmonic output power, the output frequency, and the phase noise (at 1 MHz offset) of the second harmonic oscillator A with the feedback circuit 14 connected thereto. As can be seen from FIG. 6, the connection of the feedback circuit 14 to the second harmonic oscillator A allows the oscillator A to operate with less phase noise and substantially the same oscillating frequency and without oscillation failure. It should be noted that no change was made to the second harmonic oscillator A when the feedback circuit 14 was connected to the oscillator A.

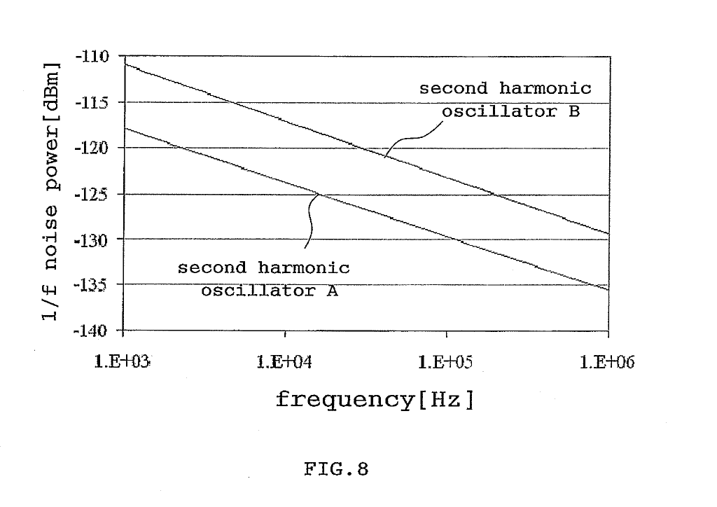

The second harmonic oscillator B differs from the second harmonic oscillator shown in FIG. 14 in that an open stub (not shown) having a length equal to a quarter of the wavelength of the fundamental signal is connected to the junction between the transmission line 115 and the open stub 116 and that the transistor 108 is replaced by a transistor which generates more 1/f noise than the transistor 108. The level of the phase noise induced by the second harmonic signal in the second harmonic oscillator B is lower than that in the second harmonic oscillator shown in FIG. 14, since in the second harmonic oscillator B the second harmonic signal is more positively caused to propagate out of the oscillator so as to reduce the amount of second harmonic signal left in the oscillator. However, since the transistor in the second harmonic oscillator B generates high 1/f noise, this oscillator has poor phase noise characteristics. It should be noted that in both second harmonic oscillators A and B, the 1/f noise increases with decreasing frequency, as shown in FIG. 8. The upper table in FIG. 7 shows the simulation results of the second harmonic output power, the output frequency, and the phase noise (at 1 MHz offset) of the second harmonic oscillator B alone (without the feedback circuit 14). The lower table in FIG. 7, on the other hand, shows the simulation results of the second harmonic output power, the output frequency, and the phase noise (at 1 MHz offset) of the second harmonic oscillator B with the feedback circuit 14 connected thereto. As can be seen from FIG. 7, the connection of the feedback circuit 14 to the second harmonic oscillator B allows the oscillator B to operate with less phase noise and substantially the same oscillating frequency and without oscillation failure. It should be noted that no change was made to the second harmonic oscillator B when the feedback circuit 14 was connected to the oscillator B. Further, in the above simulations, the first shunt capacitor 34 and the second shunt capacitor 36 are both valued at 2 pF and the high capacitance capacitor 38 is valued at 100 pF.

It should be noted that the feedback circuit 14 includes only passive components. Therefore, the second harmonic oscillators A and B with the feedback circuit 14 connected thereto generate just the same levels of 1/f noise signal as those (shown in FIG. 8) generated by the second harmonic oscillators A and B alone without the feedback circuit 14. That is, a feedback signal derived from the 1/f noise signal can be applied to the base of the transistor 16 through the feedback circuit 14 to reduce the phase noise due to 1/f noise without adding a 1/f noise source, such as a transistor, for that purpose. Further, the first electrical signal line may have a length equal to a quarter of the wavelength of the fundamental signal in order to reduce fluctuations in the base voltage of the transistor due to the second harmonic signal and hence reduce the phase noise due to the second harmonic signal. Further, the present embodiment does not require any additional bias power supply and bias terminal. Thus, the present embodiment allows a high frequency second harmonic oscillator to have a simple construction that ensures low phase noise characteristics of the oscillator by eliminating all possible causes of increase in the phase noise.

The length of the first electrical signal line 30 of the present embodiment is preferably equal to an odd multiple of a quarter of the wavelength of the fundamental signal, but not necessarily so. Specifically, in order to ensure the phase noise-reducing effect as described above, the first electrical signal line 30 must be formed to the above length with a length tolerance of ± 1/16 of the wavelength of the fundamental signal. That is, it is only necessary that the first electrical signal line 30 have a length equal to a wavelength between an odd multiple of a quarter of the wavelength of the fundamental signal plus and minus one-sixteenth of the wavelength of the fundamental signal.

The length of the second electrical signal line 32 of the present embodiment and the points at which the signal line 32 is connected to the oscillator circuit are preferably adjusted to adjust the output impedance of the oscillator so that the largest possible amount of second harmonic signal is output from the oscillator. When the output impedance of the oscillator is matched to the load impedance by a matching circuit (not shown) connected between the virtual short point 22 and the capacitor 26, the second electrical signal line 32 may have a length equal to an odd multiple of a quarter of the wavelength of the second harmonic signal, so that the signal line 32 acts as an open circuit to the second harmonic signal and does not affect the line between the virtual short point 22 and the capacitor 26. This prevents the feedback circuit 14 from affecting the output impedance and the output matching of the oscillator. As a result, the second harmonic signal can be effectively output from the output terminal. Even when the oscillator does not include the above matching circuit, the second electrical signal line 32 may have a length equal to an odd multiple of a quarter of the wavelength of the second harmonic signal, so that the signal line 32 does not affect the line between the virtual short circuit 22 and the capacitor 26. Further, the length of the second electrical signal line 32 may be adjusted so that the output impedance of the oscillator is matched to the load impedance at the frequency of the second harmonic signal.

The higher the capacitance of the high capacitance capacitor 38 of the present embodiment, the better. However, in order to ensure the phase noise-reducing effect as described above, it is only necessary that the high capacitance capacitor 38 have a capacitance five times or more greater than the capacitance of the first shunt capacitor 34 or the second shunt capacitor 36, whichever is higher. The high capacitance capacitor 38 must have a capacitance of at least 10 pF in order to effectively feedback 1/f noise at 0.001 GHz or less, which is closely related to the phase noise. The high capacitance capacitor 38 may be selected to have a capacitance of 20 pF or more to obtain a relatively high phase noise-reducing effect. That is, the capacitance of the capacitor 38 is preferably 50 pF or more, more preferably 100 pF or more, in which case a very high phase noise-reducing effect can be obtained.

In the present embodiment, the transistor 16 is a bipolar transistor made of indium gallium arsenide. However, the feedback circuit 14 can be used with a transistor made of any suitable material. That is, the transistor 16 may be made, e.g., of silicon, gallium arsenide, gallium nitride, etc. Further, the transistor 16 may have any suitable structure; it may be a bipolar transistor, a field effect transistor, or a high electron mobility transistor, or even a vacuum tube. The gate, drain, and source terminals of the field effect transistor and high electron mobility transistor correspond to the base, collector, and emitter terminals, respectively, of the bipolar transistor.

Although the present embodiment has been described in connection with a second harmonic oscillator having a series positive feedback construction, it is to be understood that the embodiment may be applied to push-push oscillators serving as second harmonic oscillators. Further, the present embodiment may also be applied to other suitable second harmonic oscillators having a virtual short point for selectively outputting the second harmonic signal.

### Second Embodiment

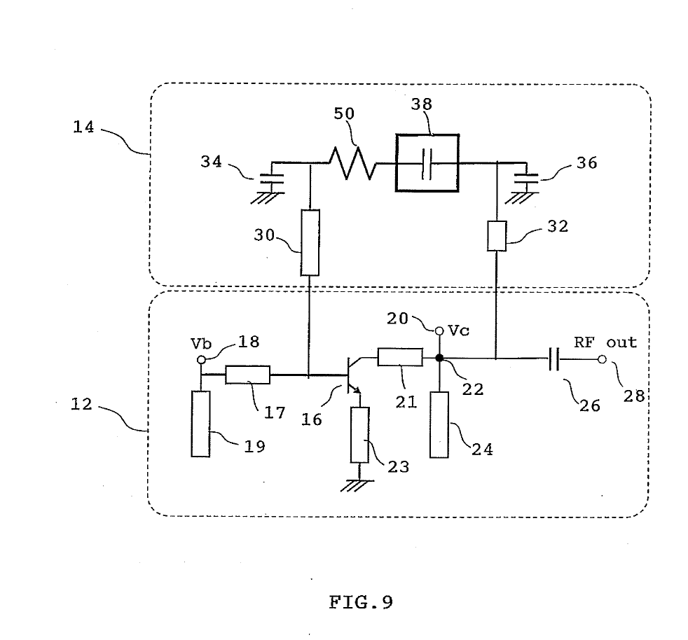

A second embodiment of the present invention will be described with reference to FIG. 9. The high frequency second harmonic oscillator of the present embodiment differs from that of the first embodiment in that it includes a resistance 50 connected in series with the high capacitance capacitor 38, which characterizes the present embodiment. It will be noted that, without the resistance 50, oscillation may occur at an undesired frequency in the loop formed by the transistor 16, the second electrical signal line 32, the high capacitance capacitor 38, and the first electrical signal line 30. The resistance 50 connected in series with the high capacitance capacitor 38 functions to suppress such unwanted oscillation. It should be noted that if the value of the resistance 50 is too high, it will also reduce the 1/f noise feedback function. Therefore, the value of the resistance 50 must be determined by taking this into account. Further, the resistance 50 may be replaced by a variable resistance which may be adjusted so that the oscillator has the desired phase noise characteristics.

### Third Embodiment

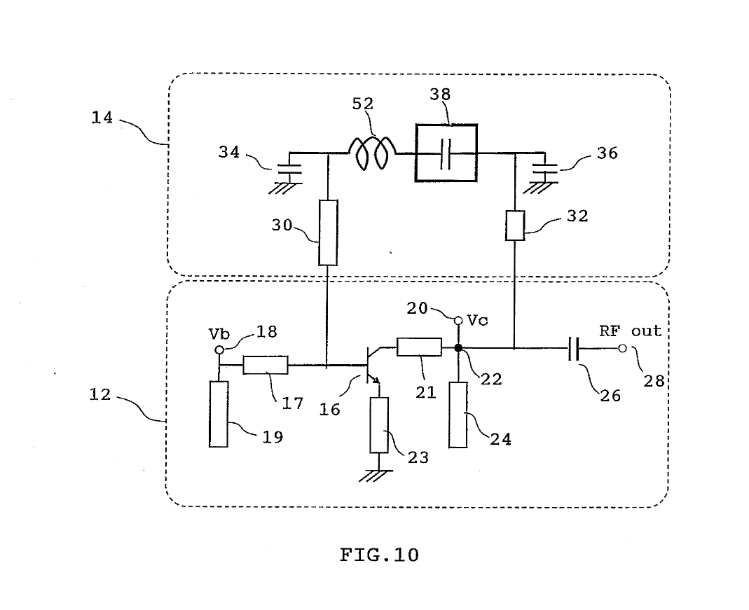

A third embodiment of the present invention will be described with reference to FIG. 10. The high frequency second harmonic oscillator of the present embodiment differs from that of the second embodiment in that the resistance 50 described above is replaced by an inductance 52 connected in series with the high capacitance capacitor 38, which characterizes the present embodiment. The inductance 52 connected in series with the high capacitance capacitor 38 does not reduce the 1/f noise feedback function as much as the resistance 50 in the second embodiment, ensuring the suppression of unwanted oscillation signals in the loop described above.

### Fourth Embodiment

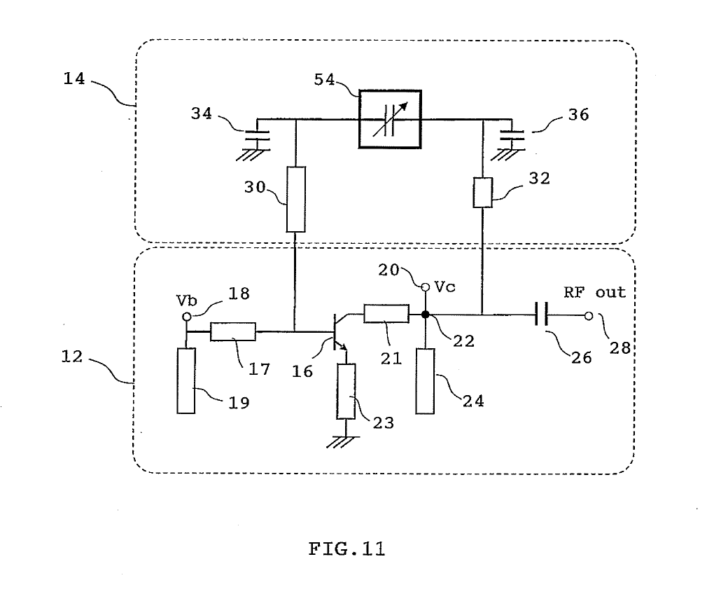

A fourth embodiment of the present invention will be described with reference to FIG. 11. The high frequency second harmonic oscillator of the present embodiment differs from that of the first embodiment in that the high capacitance capacitor 38 is replaced by a variable capacitor 54, which characterizes the present embodiment. The capacitance of the variable capacitor 54 may be adjusted to feed back an appropriate 1/f noise signal without causing unwanted oscillation.

### Fifth Embodiment

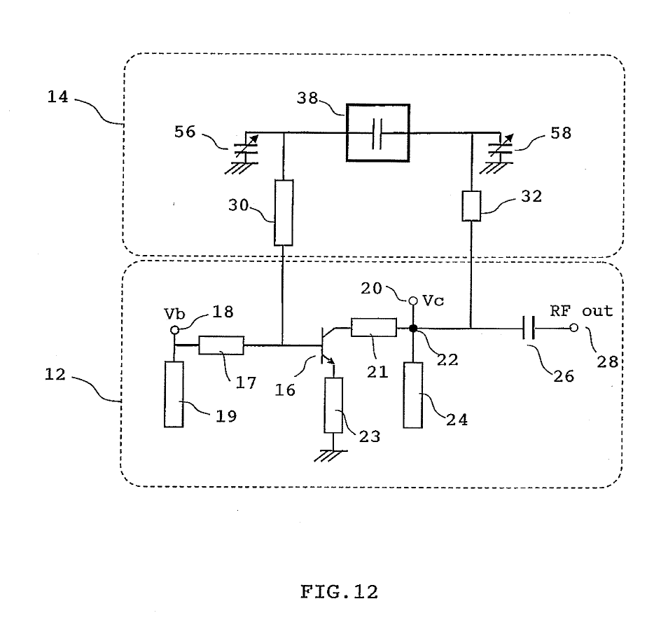

A fifth embodiment of the present invention will be described with reference to FIG. 12. The high frequency second harmonic oscillator of the present embodiment differs from that of the first embodiment in that the first shunt capacitor 34 and the second shunt capacitor 36 are replaced by a first shunt capacitor 56 and a second shunt capacitor 58, respectively, which are variable capacitors. This characterizes the present embodiment. In order for the feedback circuit to function to suppress the phase noise from the oscillating circuit 12, it is necessary that the first and second shunt capacitors act as open circuits to the low frequency 1/f noise signal and act as short circuits to the fundamental and second harmonic signals. Since the first shunt capacitor 56 and the second shunt capacitor 58 are variable capacitors, their capacitances can be adjusted so as to satisfy these requirements. It should be noted that the variable capacitor 54 of the fourth embodiment and the first shunt capacitor 56 and the second shunt capacitor 58 of the present embodiment may be implemented, e.g., with varactor diodes.

### Sixth Embodiment

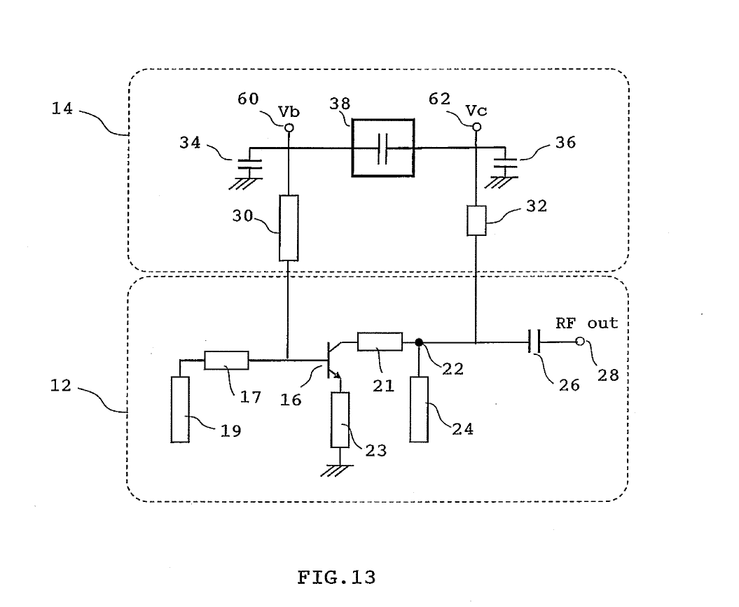

A sixth embodiment of the present invention will be described with reference to FIG. 13. The high frequency second harmonic oscillator of the present embodiment differs from that of the first embodiment in that it includes a bias terminal 60 connected between the high capacitance capacitor 38 and the first shunt capacitor 34 and also includes a bias terminal 62 connected between the high capacitance capacitor 38 and the second shunt capacitor 36. This allows the first electrical signal line 30 and the second electrical signal line 32 to be used as parts of the bias circuit. It should be noted that the constructions of any ones of the second to sixth embodiments may be combined with each other.

The present invention enables the manufacture of a high frequency second harmonic oscillator having a construction that ensures low phase noise characteristics of the oscillator by eliminating all possible causes of increase in the phase noise.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2010-007092, filed on Jan. 15, 2010 including specification, claims, drawings and summary, on which the Convention priority of the present application is based, are incorporated herein by reference in its entirety.

1. A high frequency second harmonic oscillator comprising:
a transistor having a base or a gate, and a collector or a drain;
a first electrical signal line electrically connected at a first end to the base or gate of said transistor;
a first shunt capacitor connected at a first end to a second end of said first electrical signal line and at a second end to ground;
a second electrical signal line electrically connected at a first end to the collector or drain of said transistor;
a second shunt capacitor connected at a first end to a second end of said second electrical signal line and at a second end to ground; and
a high capacitance capacitor connected between the second end of said first electrical signal line and the second end of said second electrical signal line, wherein said first electrical signal line has a length equal to an odd integer multiple of one quarter of the wavelength of a fundamental signal, plus or minus one-sixteenth of the wavelength of the fundamental signal.

2. The high frequency second harmonic oscillator according to claim 1, wherein said high capacitance capacitor has a capacitance at least five times larger than the larger of the capacitance of said first shunt capacitor and the capacitance of said second shunt capacitor.

3. The high frequency second harmonic oscillator according to claim 1, further comprising a resistance connected in series with said high capacitance capacitor.

4. The high frequency second harmonic oscillator according to claim 1, further comprising an inductance connected in series with said high capacitance capacitor.

5. The high frequency second harmonic oscillator according to claim 1, wherein said high capacitance capacitor is a variable capacitor.

6. The high frequency second harmonic oscillator according to claim 1, wherein said first and second shunt capacitors are variable capacitors.

7. The high frequency second harmonic oscillator according to claim 1, further comprising:
a first bias terminal or a first bias circuit connected at one end between said high capacitance capacitor and said first shunt capacitor; and
a second bias terminal or a second bias circuit connected between said high capacitance capacitor and said second shunt capacitor.

8. The high frequency second harmonic oscillator according to claim 3, wherein said resistance is a variable resistance.

9. The high frequency second harmonic oscillator according to claim 3, wherein said resistance is a fixed resistance.
